(19) United States
(12) Patent Application Publication
(10) Pub. No.: US 2025/0359464 A1
(43) Pub. Date: Nov. 20, 2025

(54) DISPLAY DEVICE

(71) Applicant: Samsung Display Co., LTD., Yongin-si (KR)

(72) Inventors: Boo-Kan KI, Yongin-si (KR); Ho Yun BYUN, Yongin-si (KR); Jeong In LEE, Yongin-si (KR); Seongsik CHOI, Yongin-si (KR)

(73) Assignee: Samsung Display Co., LTD., Yongin-si (KR)

(21) Appl. No.: 19/052,936

(22) Filed: Feb. 13, 2025

(30) Foreign Application Priority Data
May 20, 2024 (KR) 10-2024-0065269

(51) Int. Cl. H10K 59/80; H10H 29/854; H10K 102/00

(52) U.S. Cl. CPC H10K 59/871; H10H 29/854; H10K 59/873; H10K 59/8791; H10K 2102/351

(57) ABSTRACT

Provided is a display device including: a display panel; a protective layer disposed on the display panel; a window disposed on the protective layer; and an adhesive layer disposed between the window and the protective layer, wherein the adhesive layer includes: a first sub-adhesive layer having a first modulus; and a second sub-adhesive layer disposed on the first sub-adhesive layer and having a second modulus, and the second modulus of the second sub-adhesive layer is greater than the first modulus of the first sub-adhesive layer.

### CROSS-REFERENCE TO RELATED APPLICATION

This application claims priority to and the benefit of Korean Patent Application No. 10-2024-0065269 under 35 U.S.C. § 119, filed on May 20, 2024, in the Korean Intellectual Property Office, the entire contents of which are incorporated herein by references.

### BACKGROUND

### 1. Technical Field

The disclosure relates to a display device.

### 2. Description of the Related Art

Electronic devices such as smartphones, mobile phones, tablets, multimedia players, televisions, and monitors include display devices for displaying images. Each of the display devices includes a display panel that implements a screen displaying an image. A flexible display device capable of deformation such as bending, folding, rolling, and stretching are being developed using a flexible substrate as a substrate for a display panel. Among flexible display devices, a foldable display device may be folded and unfolded like a book.

### SUMMARY

Embodiments attempt to provide a display device with excellent impact resistance and reduced external light reflection.

An embodiment of the disclosure provides a display device including: a display panel, a protective layer disposed on the display panel, a window disposed on the protective layer, and an adhesive layer disposed between the window and the protective layer, wherein the adhesive layer includes: a first sub-adhesive layer having a first modulus; and a second sub-adhesive layer disposed on the first sub-adhesive layer and having a second modulus, and the second modulus of the second sub-adhesive layer is greater than the first modulus of the first sub-adhesive layer.

The first modulus of the first sub-adhesive layer may be about 0.1 MPa or less.

The second modulus of the second sub-adhesive layer may be about 100 MPa or more.

A thickness of the first sub-adhesive layer may be greater than that of the second sub-adhesive layer in a thickness direction.

The thickness of the first sub-adhesive layer may be about 50 μm or more, and the thickness of the second sub-adhesive layer may be about 25 μm to about 30 μm.

The protective layer may have a first refractive index, and the window may have a second refractive index.

The first sub-adhesive layer and the second sub-adhesive layer may have the second refractive index.

The first sub-adhesive layer and the second sub-adhesive layer may have the first refractive index.

The first sub-adhesive layer may have the first refractive index, and the second sub-adhesive layer may have the second refractive index.

At least one of the first sub-adhesive layer or the second sub-adhesive layer may include at least one of a fluorene-based compound, a sulfone-based compound, or a TiO2 nanocomposite.

An embodiment of the disclosure provides a display device including: a display panel, a window disposed on the display panel, and an adhesive layer disposed between the window and the display panel, wherein the adhesive layer includes: a first sub-adhesive layer having a first modulus, and a second sub-adhesive layer disposed on the first sub-adhesive layer and having a second modulus, and the second modulus of the second sub-adhesive layer is greater than the first modulus of the first sub-adhesive layer.

The first sub-adhesive layer may be in contact with the display panel.

The second sub-adhesive layer may be in contact with the window.

The first modulus may be about 0.1 MPa or less, and the second modulus may be about 100 MPa or more.

A thickness of the first sub-adhesive layer may be greater than a thickness of the second sub-adhesive layer in a thickness direction.

The thickness of the first sub-adhesive layer may be about 50 μm or more.

The thickness of the second sub-adhesive layer may be about 50 μm to about 60 μm.

The window may have a second refractive index.

The first sub-adhesive layer and the second sub-adhesive layer may have the second refractive index.

At least one of the first sub-adhesive layer or the second sub-adhesive layer may include at least one of a fluorene-based compound, a sulfone-based compound, or a TiO2 nanocomposite.

According to the embodiments, it may be possible to provide a foldable display device with improved durability against external impact. Additionally, according to embodiments, it may be possible to provide a display device that provides improved color by reducing external light reflection.

### BRIEF DESCRIPTION OF THE DRAWINGS

FIG. 1 illustrates a schematic perspective view of a display device according to an embodiment.

FIG. 2 illustrates a schematic cross-sectional view taken along line I-I′ of FIG. 1 according to an embodiment.

FIG. 3 illustrates an enlarged schematic view of a partial configuration of a display device according to an embodiment.

FIG. 4 illustrates a schematic cross-sectional view taken along line I-I′ of FIG. 1 according to another embodiment.

FIG. 5 illustrates an enlarged schematic view of a partial configuration of a display device according to another embodiment.

FIG. 6 illustrates a schematic cross-sectional view of a stacked structure of a display panel according to an embodiment.

FIG. 7 to FIG. 9 illustrate schematic cross-sectional views of stacked structures according to a comparative example and an example.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements. When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within +20%, +10%, or +5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention. Further, throughout the specification, the phrase “in a plan view” means when an object portion is viewed from above, and the phrase “in a cross-sectional view” means when a cross-section taken by vertically cutting an object portion is viewed from the side.

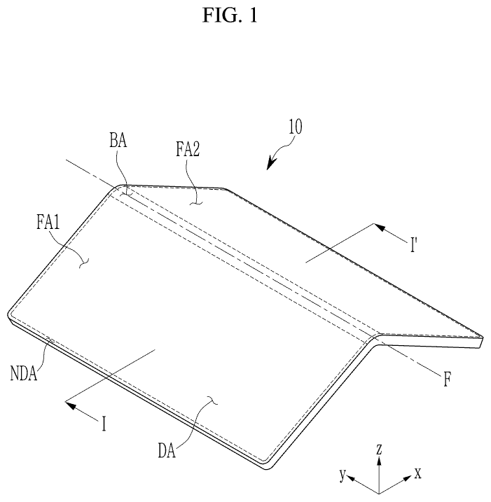

A display device according to an embodiment of the disclosure will be described with reference to FIG. 1. FIG. 1 illustrates a schematic perspective view of a display device according to an embodiment.

Referring first to FIG. 1, a first direction x is a direction parallel to a first side of the display device 10 in a plan view, and may be, for example, a horizontal direction of the display device 10. A second direction y is a direction parallel to a second side that is in contact with the first side of the display device 10 in a plan view, and may be a vertical direction of the display device 10. A third direction z may be a thickness direction of the display device 10.

The display device 10 includes a display area DA where an image is displayed and a non-display area NDA excluding the display area. The display area DA may be an area that displays an image by including a plurality of pixels. The non-display area NDA, which is an area that does not include pixels, may be disposed around the display area DA.

The display device 10 may be unfolded flatly as a whole. The display device 10 may include a first flat area FA1, a second flat area FA2, and a foldable area BA disposed between the first flat area FA1 and the second flat area FA2. The foldable area BA may be an area that is folded in case that folded based on a folding axis F, and the first flat area FA1 and the second flat area FA2 are areas that are not folded. The foldable area BA may be folded around an axis that is parallel to the second direction y.

Although FIG. 1 shows one foldable area BA, the display device 10 according to an embodiment may include one or more foldable areas BA. One or more foldable areas BA may be folded around different axes, for example, an axis parallel to the first direction x and/or an axis parallel to the second direction y, and a position and a width of the foldable area BA may be changed in various ways in the display device 10.

The display device 10 may maintain both folded and unfolded states. The display device 10 may be folded using an in-folding method in which the display area DA is disposed on the inside, or an out-folding method in which the display area DA is disposed on the outside. In case that the display device 10 is folded using the in-folding method, front surfaces of the display device 10 may face each other. In case that the display device 10 is folded using the out-folding method, back surfaces of the display device 10 may face each other.

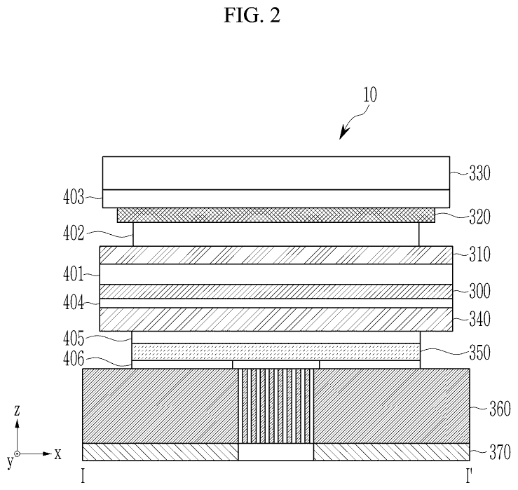

A stacked structure of a display device according to an embodiment will be described with reference to FIG. 2. FIG. 2 is a schematic cross-sectional view taken along line I-I′ of FIG. 1.

Referring to FIG. 2, according to an embodiment, the display device 10 may include a window protective film 330, a window 320, a first protective layer 310, a display panel 300, a second protective layer 340, a barrier film 350, a support member 360, and a cushion member 370.

Each component constituting the display device 10 may be attached by first to sixth adhesive layers 401, 402, 403, 404, 405, and 406. The adhesive layers 401, 402, 403, 404, 405, and 406 may be pressure-sensitive adhesive (PSA). Each of the adhesive layers 401, 402, 403, 404, 405, and 406 may be an optically clear adhesive (OCA) film or an optically clear resin (OCR). Each of the adhesive layers 401, 402, 403, 404, 405, and 406 may be the same or different.

The display panel 300 may be any one of a light emitting display panel, a liquid crystal display panel, a plasma display panel, an electrophoretic display panel, a microelectromechanical system (MEMS) display panel, and an electrowetting display panel.

The first protective layer 310 may be disposed on the display panel 300, and may protect the display panel 300. According to another embodiment, the first protective layer 310 may function to prevent external light reflection by preventing light from being reflected from inside the display panel 300 and escaping.

Although not shown in this specification, in another embodiment, the first protective layer 310 may be disposed between the window 320 and the window protective film 330, which will be described later. The first protective layer 310 may include, for example, a polyethylene terephthalate resin.

The window 320 may be disposed on a front surface of the first protective layer 310 and serve to protect the display panel 300. The window 320 may be attached to the front surface of the first protective layer 310 by the second adhesive layer 402. The window 320 is made of a transparent material, and it may include, for example, glass or plastic. For example, the window 320 may include ultra-thin glass (UTG) with a thickness of about 0.1 mm or less, transparent polyimide, polyethylene terephthalate (PET), polycarbonate (PC), etc.

The window protective film 330 may be disposed on the front surface of the window 320. The window protective film 330 may be attached to the front surface of the window 320 by the third adhesive layer 403. The window protective film 330 may perform at least one of the functions of preventing the window 320 from scattering, absorbing shock, preventing scratches, preventing fingerprints, and preventing glare.

The second protective layer 340 may be disposed on a back surface of the display panel 300. The second protective layer 340 may be attached to the back surface of the display panel 300 by the fourth adhesive layer 404. The second protective layer 340 may support the display panel 300, and may serve to protect the back surface of the display panel 300.

The barrier film 350 may be disposed on the back surface of the second protective layer 340. The barrier film 350 may be attached to the back of the second protective layer 340 by the fifth adhesive layer 405. The barrier film 350 may prevent moisture and oxygen from penetrating from the outside. According to an embodiment, the barrier film 350 may be omitted.

The support member 360 may be disposed on a back surface of the barrier film 350 to increase strength and rigidity of the display device 10. The support member 360 may be attached to the back surface of the barrier film 350 by the sixth adhesive layer 406. The sixth adhesive layer 406 may not be disposed in the foldable area BA to reduce folding stress in case that the display device 10 is folded. The sixth adhesive layer 406 may be a pressure-sensitive adhesive (PSA).

The support member 360 may include at least one reinforcing fiber composite material according to another embodiment. For example, the support member 360 may include at least one of carbon fiber reinforced plastic (CFRP) or glass fiber reinforced plastic (GFRP). According to another embodiment, the support member 360 may include a metal such as SUS, Al, Mg, or Ti.

An embodiment in which the support member 360 is disposed between the cushion member 370 and the second barrier film 350 is shown, but the disclosure is not limited thereto, and the support member 360 may be disposed on a lower surface of the cushion member 370 according to another embodiment. The cushion member 370 may be disposed below the support member 360.

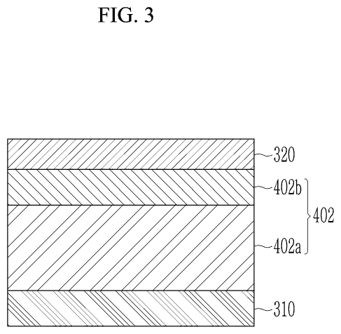

An adhesive layer 402 between the first protective layer 310 and the window 320 will be described with reference to FIG. 3. FIG. 3 illustrates an enlarged schematic view of a partial configuration of a display device according to an embodiment.

Referring to FIG. 3, the adhesive layer 402 may be disposed between the first protective layer 310 and the window 320. The adhesive layer 402 may couple the first protective layer 310 and the window 320.

The adhesive layer 402 may include a first sub-adhesive layer 402a disposed on the first protective layer 310 and a second sub-adhesive layer 402b disposed on the first sub-adhesive layer 402a. The first sub-adhesive layer 402a may be in contact with the first protective layer 310. The second sub-adhesive layer 402b may be in contact with the window 320.

The first sub-adhesive layer 402a may have a first modulus. For example, the first modulus may be about 0.1 MPa or less and may have a relatively low modulus. The first sub-adhesive layer 402a may have an adhesive function, and may provide folding characteristics.

A thickness of the first sub-adhesive layer 402a may be about 50 μm or more. In case that the thickness of the first sub-adhesive layer 402a satisfies the numerical range, it may provide appropriate folding characteristics and adhesive characteristics.

The second sub-adhesive layer 402b may have a second modulus. For example, the second modulus may be about 100 MPa or more and may have a relatively high modulus. The second sub-adhesive layer 402b may improve impact resistance against external impact.

The first sub-adhesive layer 402a and the second sub-adhesive layer 402b may have the same compounds, but may be provided to have different moduli by adjusting a mixing ratio of the compounds included.

The modulus used in this specification may represent a mechanical characteristic indicating rigidity of a corresponding layer. For example, a degree of deformation due to an external force (or impact) given in the first sub-adhesive layer 402a having a relatively low modulus is greater than a degree of deformation due to an external force in the second sub-adhesive layer 402b having a relatively high modulus.

The thickness of the second sub-adhesive layer 402b may be about 25 μm to about 30 μm. If the thickness of the second sub-adhesive layer 402b satisfies the numerical range, it may provide a folding characteristic and may have an appropriate impact-resistance characteristic.

The thickness of the first sub-adhesive layer 402a may be greater than the thickness of the second sub-adhesive layer 402b. In case that the thickness of the first sub-adhesive layer 402a is greater than the thickness of the second sub-adhesive layer 402b, it may provide a folding characteristic while having appropriate impact resistance.

The first protective layer 310 may have a first refractive index, and for example, the refractive index of the first protective layer 310 may be about 1.65. The window 320 may have a second refractive index, and for example, the refractive index of the window 320 may be about 1.51, which is less than the refractive index of the first protective layer 310.

The first sub-adhesive layer 402a may have the same refractive index as the first protective layer 310. The first sub-adhesive layer 402a may have a first refractive, for example, a first refractive index of about 1.65. For example, the second sub-adhesive layer 402b may have the same refractive index as the first protective layer 310, as may the first sub-adhesive layer 402a. The second sub-adhesive layer 402b may have a first refractive index—for example, a refractive index of about 1.65.

In order for the first sub-adhesive layer 402a and the second sub-adhesive layer 402b to have a first refractive index, each of the first sub-adhesive layer 402a and the second sub-adhesive layer 402b may include at least one of a fluorene-based compound, a sulfone-based compound, or a TiO2 nanocomposite.

In the case of the fluorene-based compound and the sulfone-based compound, a refractive index of the corresponding layer may be efficiently increased by including a substituent with a high-molecular refractive index and a low molar volume. For example, the substituent may include a cyclic aromatic compound, fluorine halogen atoms, and sulfur atoms. A TiO2 nanocomposite, which is a high concentration of TiO2 nanoparticles dispersed in a transparent polymer, may provide a relatively high refractive index while maintaining a transparency of an adhesive layer.

The disclosure is not limited thereto, and according to another embodiment, the first sub-adhesive layer 402a and the second sub-adhesive layer 402b may have the same refractive index as the window 320. The first sub-adhesive layer 402a and the second sub-adhesive layer 402b may have a second refractive index, for example, a refractive index of about 1.51.

According to another embodiment, the first sub-adhesive layer 402a may have the same refractive index as the first protective layer 310. The first sub-adhesive layer 402a may have a first refractive index, for example, a refractive index of about 1.65. For example, the second sub-adhesive layer 402b may have the same refractive index as the window 320. The second sub-adhesive layer 402b may have a second refractive index, for example, a refractive index of about 1.51.

The first protective layer 310, the first sub-adhesive layer 402a, the second sub-adhesive layer 402b, and the window 320 may be divided into two regions having two different refractive indices. The stacked structure may be divided into four layers, but considering the refractive index, it may be divided into two regions with different refractive indices. For example, reflection may occur at an interface between the two regions. For example, the refractive indices of the first and second sub-adhesive layers may be controlled to minimize interfaces with different refractive indices, minimizing external light reflection.

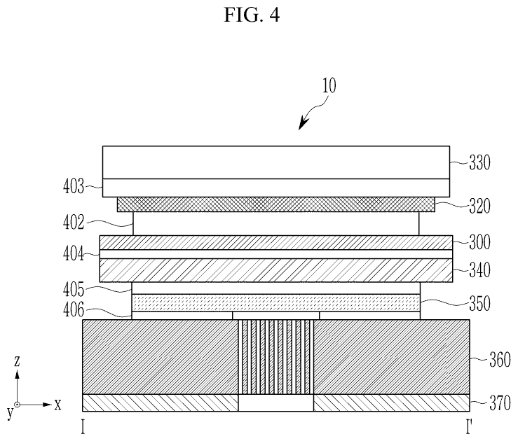

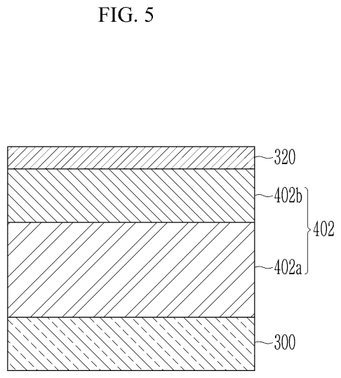

A display device according to another embodiment of the disclosure will be described with reference to FIG. 4 and FIG. 5. FIG. 4 illustrates a schematic cross-sectional view taken along line I-I′ of FIG. 1 according to another embodiment, and FIG. 5 illustrates an enlarged schematic view of a partial configuration of a display device according to another embodiment. A description of components that are the same or similar to the components described above will be omitted.

Referring to FIG. 4, the display device 10 may include a window protective film 330, a window 320, a display panel 300, a second protective layer 340, a barrier film 350, a support member 360, and a cushion member 370.

Each component constituting the display device 10 may be attached by adhesive layers 402, 403, 404, 405, and 406. The adhesive layers 402, 403, 404, 405, and 406 may be pressure-sensitive adhesive (PSA). Each of the adhesive layers 402, 403, 404, 405, and 406 may each be an optically clear adhesive (OCA) film or an optically clear resin (OCR). Each of the adhesive layers 402, 403, 404, 405, and 406 may be the same or different.

Unlike the display device described in FIG. 3, the display device 10 according to an embodiment may not include a first protective layer, and may be a slimmer display device.

Referring to FIG. 5, the adhesive layer 402 may be disposed between the display panel 300 and the window 320. The adhesive layer 402 may couple the display panel 300 and the window 320.

The adhesive layer 402 may include a first sub-adhesive layer 402a disposed on the display panel 300 and a second sub-adhesive layer 402b disposed on the first sub-adhesive layer 402a. The first sub-adhesive layer 402a may be in contact with the display panel 300. The second sub-adhesive layer 402b may be in contact with the window 320.

The first sub-adhesive layer 402a may have a first modulus. For example, the first modulus may be about 0.1 MPa or less and may have a relatively low modulus. The first sub-adhesive layer 402a may have an adhesive function, and may provide folding characteristics.

The thickness of the first sub-adhesive layer 402a may be about 50 μm or more and about 150 μm or less. In case that the thickness of the first sub-adhesive layer 402a satisfies the numerical range, it may provide appropriate folding characteristics and adhesive characteristics.

The second sub-adhesive layer 402b may have a second modulus. For example, the second modulus may be about 100 MPa or more and may have a relatively high modulus. The second sub-adhesive layer 402b may improve impact resistance against external impacts.

The thickness of the second sub-adhesive layer 402b may be about 50 μm to about 60 μm. In case that the thickness of the second sub-adhesive layer 402b satisfies the numerical range, it may provide a folding characteristic while having an appropriate impact-resistance characteristic.

The thickness of the first sub-adhesive layer 402a may be greater than the thickness of the second sub-adhesive layer 402b in the thickness direction. In case that the thickness of the first sub-adhesive layer 402a is greater than the thickness of the second sub-adhesive layer 402b, it may provide a folding characteristic while having an appropriate impact-resistance characteristic.

The window 320 may have a second refractive index—for example, the refractive index of the window 320 may be about 1.51.

According to another embodiment, the first sub-adhesive layer 402a may have a first refractive index, for example, a refractive index of about 1.65. For example, like the first sub-adhesive layer 402a, the second sub-adhesive layer 402b may have a first refractive index, for example, a refractive index of about 1.65.

In order for the first sub-adhesive layer 402a and the second sub-adhesive layer 402b to have the first refractive index, each of the first sub-adhesive layer 402a and the second sub-adhesive layer 402b may include at least one of a fluorene-based compound, a sulfone-based compound, or a TiO₂ nanocomposite.

In the case of the fluorene-based compound and the sulfone-based compound, a refractive index of the corresponding layer may be efficiently increased by including a substituent with a high-molecular refractive index and a low molar volume. For example, the substituent may include a cyclic aromatic compound, fluorine halogen atoms, and sulfur atoms. A TiO₂ nanocomposite, which is a high concentration of TiO₂ nanoparticles dispersed in a transparent polymer, may provide a relatively high refractive index while maintaining transparency of an adhesive layer.

According to the above-described embodiments, the sub-adhesive layer 402a, the second sub-adhesive layer 402b, and the window 320 may be divided into two regions having two different refractive indices. The stacked structure may be divided into three layers, but considering the refractive index, it may be divided into two regions with different refractive indices. For example, reflection may occur at an interface between the two regions. For example, the refractive indices of the first and second sub-adhesive layers may be controlled to minimize interfaces with different refractive indices, minimizing external light reflection.

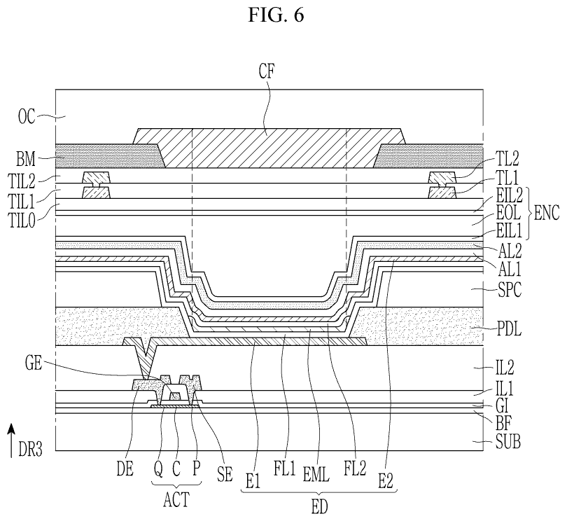

A stacked structure of a display panel according to an embodiment will be described with reference to FIG. 6. FIG. 6 illustrates a schematic cross-sectional view of a stacked structure of a display panel according to an embodiment.

Referring to FIG. 6, the display panel 300 may include a substrate SUB. The substrate SUB may include an inorganic insulating material such as glass, or an organic insulating material such as plastic, for example, polyimide (PI). The substrate SUB may be a single-layer or a multi-layer structure. The substrate SUB may have a structure in which at least one base layer including a sequentially stacked polymer resin and at least one alternately stacked inorganic layer.

The substrate SUB may have various degrees of flexibility. The substrate SUB may be a rigid substrate or a flexible substrate capable of bending, folding, rolling, or the like.

A buffer layer BF may be disposed on the substrate SUB. The buffer layer BF may prevent impurities from being transferred from the substrate SUB to an upper layer of the buffer layer BF, particularly a semiconductor layer ACT, thereby preventing deterioration of a characteristic of the semiconductor layer ACT and reducing stress. The buffer layer BF may include an inorganic insulating material such as a silicon nitride or a silicon oxide, or may include an organic insulating material. In another embodiment, a portion or all of the buffer layer BF may be omitted.

The semiconductor layer ACT may be disposed on the buffer layer BF. The semiconductor layer ACT may include at least one of polysilicon and an oxide semiconductor. The semiconductor layer ACT may include a channel region C, a first region P, and a second region Q. The first region p and the second region Q may be disposed at opposite sides of the channel region C. For example, the channel region may be disposed between the first region P and the second region Q. The channel region C may be doped with a small amount of impurities or may be a semiconductor that is not doped with impurities, and the first region P and the second region Q may include a semiconductor doped with a large amount of impurities compared to the channel region C. The semiconductor layer ACT may be formed by using an oxide semiconductor, and for example, a separate protective layer (not illustrated) may be added to protect an oxide semiconductor material that is vulnerable to external environments such as high temperatures.

A gate insulating layer GI may be disposed on the semiconductor layer ACT. The gate insulating layer GI may be a single layer or multiple layers including at least one of silicon oxide (SiOₓ), silicon nitride (SiNₓ), and silicon oxynitride (SiOₓN_{y}).

A gate electrode GE may be disposed on the gate insulating layer GI. The gate electrode GE may be a single-layer or a multi-layer structure in which a metal layer including any one of copper (Cu), a copper alloy, aluminum (Al), an aluminum alloy, molybdenum (Mo), a molybdenum alloy, titanium (Ti), and a titanium alloy is stacked. The gate electrode GE may overlap the channel region C of the semiconductor layer ACT in the thickness direction.

A first insulating layer IL1 may be disposed on the gate electrode GE and the gate insulating layer GI. The first insulating layer IL1 may be a single layer or multiple layers including at least one of silicon oxide (SiOₓ), silicon nitride (SiNₓ), and silicon oxynitride (SiOₓN_{y}).

A source electrode SE and a drain electrode DE may be disposed on the first insulating layer IL1. Each of the source electrode SE and the drain electrode DE may be electrically connected to the first region P and the second region Q of the semiconductor layer ACT through contact holes formed in the first insulating layer IL1.

The source electrode SE and the drain electrode DE may include aluminum (Al), silver (Ag), magnesium (Mg), gold (Au), nickel (Ni), chromium (Cr), calcium (Ca), molybdenum (Mo), titanium (Ti), tungsten (W), copper (Cu), and/or the like, and may have a single-layer or multi-layer structure including the material.

A second insulating layer IL2 may be disposed on the first insulating layer IL1, the source electrode SE, and the drain electrode DE. The second insulating layer IL2 may include a general-purpose polymer such as poly (methyl methacrylate) (PMMA) or polystyrene (PS), a polymer derivative having a phenolic group, an organic insulating material such as an acrylic polymer, an imide polymer, a polyimide, an acrylic polymer, a siloxane polymer, etc. This specification shows the second insulating layer IL2 formed as a single-layer structure, but the disclosure is not limited thereto, and it may be formed as a multi-layer structure.

A first electrode E1 may be disposed on the second insulating layer IL2. The first electrode E1 may be electrically connected to the drain electrode DE through a contact hole of the second insulating layer IL2.

The first electrode E1 may include a metal such as silver (Ag), lithium (Li), calcium (Ca), aluminum (Al), magnesium (Mg), and gold (Au), and may also include a transparent conductive oxide (TCO) such as an indium zinc oxide (IZO) and an indium tin oxide (ITO). The first electrode E1 may be formed as a single layer including a metal material or a transparent conductive oxide, or multiple layers including the same. For example, the first electrode E1 may have a triple-layer structure of indium tin oxide (ITO)/silver (Ag)/indium tin oxide (ITO).

A transistor including the gate electrode GE, the semiconductor layer ACT, the source electrode SE, and the drain electrode DE may be electrically connected to the first electrode E1 to supply a current to a light emitting element.

A pixel defining layer PDL may be disposed on the second insulating layer IL2 and the first electrode E1.

The pixel defining layer PDL may include an insulating material. In another embodiment, the pixel defining layer PDL may include an inorganic insulating material such as silicon nitride, silicon oxynitride, or silicon oxide. In still another embodiment, the pixel defining layer PDL may include an organic insulating material and an inorganic insulating material. The pixel defining layer PDL may include a light blocking material, and may be provided in black. The light blocking material may include carbon black, carbon nanotubes, a resin or paste containing a black dye, metal particles such as nickel, aluminum, molybdenum, and alloys thereof, metal oxide particles (e.g., chromium oxide) or metal nitride particles (e.g., chromium nitride) and the like. In case that the pixel defining layer PDL includes a light blocking material, external light reflection caused by metal structures disposed below the pixel defining layer PDL may be reduced. However, the disclosure is not limited thereto. In another example, the pixel defining layer (PDL) may not include a light blocking material, but may include a light transmitting organic insulating material.

A spacer SPC may be disposed on the pixel defining layer PDL. The spacer SPC may include an organic insulating material such as polyimide. In another embodiment, the spacer SPC may include an inorganic insulating material such as silicon nitride (SiNₓ) or silicon oxide (SiO₂), or may include an organic insulating material and an inorganic insulating material.

In an embodiment, the spacer SPC may include a same material as the pixel defining layer PDL. For example, the pixel defining layer PDL and the spacer SPC may be formed together in a mask process using a halftone mask or the like. The pixel defining layer PDL and spacer SPC may include different materials.

A light emitting layer EML may be disposed on the first electrode E1. The light emitting layer EML may include an organic material and/or an inorganic material. The light emitting layer EML may generate a predetermined color light. The light emitting layer EML may be formed to be disposed only in an opening of the pixel defining layer using a mask or an inkjet process.

A first functional layer FL1 may be disposed between the light emitting layer EML and the first electrode E1, and a second functional layer FL2 may be disposed between the light emitting layer EML and the second electrode E2.

The first functional layer FL1 may include at least one of a hole injection layer or a hole transporting layer, and the second functional layer FL2 may include at least one of an electron transporting layer or an electron injection layer.

As the light emitting layer EML may be disposed for each pixel to correspond to the opening of the pixel defining layer PDL, each of the first functional layer FL1 and the second functional layer FL2 may be integrally formed to cover the entire substrate SUB. For example, the first functional layer FL1 and the second functional layer FL2 may be formed integrally to cover the entire display area of the substrate SUB.

A second electrode E2 may be disposed on the light emitting layer EML.

The second electrode E2 may include a reflective metal including calcium (Ca), barium (Ba), magnesium (Mg), aluminum (Al), silver (Ag), gold (Au), nickel (Ni), chromium (Cr), lithium (Li), calcium (Ca), molybdenum (Mo), etc., or a transparent conductive oxide (TCO), such as an indium tin oxide (ITO) or an indium zinc oxide (IZO).

The first electrode E1, the light emitting layer EML, and second electrode E2 may constitute a light emitting element ED. The first electrode E1 may be an anode which is a hole injection electrode, and the second electrode E2 may be a cathode which is an electron injection electrode. However, the present embodiment is not limited thereto, and the first electrode E1 may be a cathode and the second electrode E2 may be an anode depending on a driving method of a light emitting display device.

In case that holes and electrons are injected from the first electrode E1 and the second electrode E2 into the light emitting layer EML, excitons formed by combining the injected holes and electrons may be emitted in case that they fall from an excited state to a ground state.

A first capping layer AL1 may be disposed on the second electrode E2. The first capping layer AL1 may serve to improve luminous efficiency of the light emitting element ED by a principle of constructive interference.

The first capping layer AL1 may be an organic capping layer including an organic material, an inorganic capping layer including an inorganic material, or a composite capping layer including an organic material and an inorganic material. For example, the first capping layer AL1 may include carbocyclic compounds, heterocyclic compounds, amine group-containing compounds, porphine derivatives, phthalocyanine derivatives, naphthalocyanine derivatives, alkali metal complexes, alkaline earth metal complexes, or any combination thereof. Carbocyclic compounds, heterocyclic compounds and amine group-containing compounds may optionally be substituted with substituents including O, N, S, Se, Si, F, Cl, Br, I, or any combination thereof.

A low-reflection layer AL2 may be disposed on the first capping layer AL1. Since the first capping layer AL1 may be disposed on the light emitting element ED, the low-reflection layer AL2 may be said to be disposed on the light emitting element ED. The low-reflection layer AL2 may overlap a front surface of the substrate SUB in the third direction (e.g., thickness direction).

The low-reflection layer AL2 may include an inorganic material having low reflectivity, and may include a metal or a metal oxide according to an embodiment. In case that the low-reflection layer AL2 contains a metal, it may include, for example, ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or a combination thereof. In addition, in case that the low-reflection layer AL2 contains a metal oxide, it may include, for example, SiO₂, TiO₂, ZrO₂, Ta₂O₅, HfO₂, Al₂O₃, ZnO, Y₂O₃, BeO, MgO, PbO₂, WO₃, SiNₓ, LiF, CaF₂, MgF₂, CdS or a combination thereof.

According to another embodiment, the first capping layer AL1 and the low-reflection layer AL2 may be omitted.

An encapsulation layer ENC may be disposed on the low-reflection layer AL2. The encapsulation layer ENC may cover and seal not only the upper surface of the light emitting element but also the side surfaces. The light emitting element ED may be vulnerable to moisture and oxygen so that the encapsulation layer ENC encapsulates the light emitting element ED to block an inflow of external moisture and oxygen.

The encapsulation layer ENC may include a plurality of layers, and among them, may be formed of a composite film including both an inorganic layer and an organic layer, and for example, may be formed as a triple layer in which a first inorganic encapsulation layer EIL1, an encapsulation organic layer EOL, and a second inorganic encapsulation layer EIL2 are sequentially formed in the third direction DR3.

The first encapsulation inorganic layer EIL1 may cover the second electrode E2. The first encapsulation inorganic layer EIL1 may prevent external moisture or oxygen from penetrating into the light emitting element. For example, the first encapsulation inorganic layer EIL1 may include silicon nitride, silicon oxide, silicon oxynitride, or a combination thereof. The first encapsulation inorganic layer EIL1 may be formed through a deposition process.

The encapsulation organic layer EOL may be disposed on the first encapsulation inorganic layer EIL1 to contact the first encapsulation inorganic layer EIL1. Curves formed on an upper surface of the first encapsulation inorganic layer EIL1 or particles present on the first encapsulation inorganic layer EIL1 may be covered by the encapsulation organic layer EOL to block an influence of a surface state of the upper surface of the first encapsulation inorganic layer EIL1 on the components formed on the encapsulation organic layer EOL. The encapsulation organic layer EOL may relieve stress between the layers that are in contact. The encapsulation organic layer EOL may include an organic material, and may be formed through a solution process such as spin coating, slit coating, or an inkjet process.

The second encapsulation inorganic layer EIL2 may be disposed on the encapsulation organic layer EOL to cover the encapsulation organic layer EOL. The second encapsulation inorganic layer EIL2 may be formed on a relatively flat surface compared to that of the first encapsulation inorganic layer EIL1. The second encapsulation inorganic layer EIL2 encapsulates moisture or the like emitted from the encapsulation organic layer EOL, to prevent it from being introduced to the outside. The second encapsulation inorganic layer EIL2 may include silicon nitride, silicon oxide, silicon oxynitride, or a combination thereof. The second encapsulation inorganic layer EIL2 may be formed through a deposition process.

A first insulating layer TIL0, a first conductive layer TL1, a first touch insulating layer TIL1, a second conductive layer TL2, and a second touch insulating layer TIL2 may be disposed on the encapsulation layer ENC. The first insulating layer TIL0, the first conductive layer TL1, the first touch insulating layer TIL1, the second conductive layer TL2, and the second touch insulating layer TIL2 may constitute a touch sensor.

A light blocking layer BM may be disposed on the second touch insulating layer TIL2. The light blocking layer BM may include an opening that overlaps the light emitting layer EML. The light blocking layer BM may overlap at least a portion of the pixel defining layer PDL.

A color filter CF may be disposed between adjacent light blocking layers BM to cover the opening. The color filter CF may reduce external light reflection while increasing the color purity of light emitted from the light emitting element ED. The display device according to the present embodiment may have the above-described stacked structure without using a polarization film to reduce external light reflection.

An overcoating layer OC may be disposed on the color filter CF and the light blocking layer BM. The overcoating layer OC may include an organic insulating material. The adhesive layer 401 described in FIG. 2 may be disposed on the overcoating layer OC, or the adhesive layer 402 described in FIG. 4 may be disposed thereon.

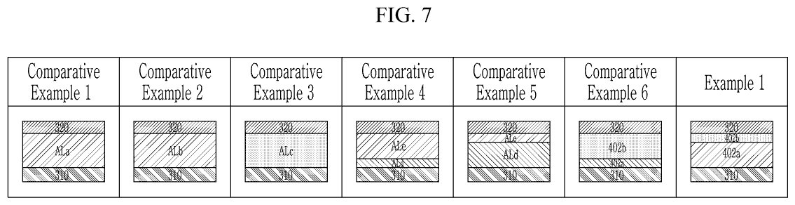

Characteristics of stacked structures according to comparative examples and examples will be examined with reference to FIGS. 7 to 9. FIG. 7 to FIG. 9 illustrate schematic cross-sectional views of stacked structures according to a comparative example and an example.

For FIG. 7 and Table 1, in Comparative Example 1, a single adhesive layer ALa having a modulus of about 0.071 MPa may be disposed between the protective layer 310 and the window 320, in Comparative Example 2, a single adhesive layer ALb with a modulus of about 0.044 MPa may be disposed between the protective layer 310 and the window 320, and in Comparative Example 3, a single adhesive layer ALc having a modulus of about 1000 MPa may be disposed between the protective layer 310 and the window 320. In Comparative Examples 4 and 5, a first sub-adhesive layer ALd having a high modulus of about 1000 MPa may be included on the first protective layer 310, and a second sub-adhesive layer ALe having a low modulus of about 0.044 MPa is included on the first sub-adhesive layer ALd. In Comparative Example 6 and Example 1, a first sub-adhesive layer 402a having a low modulus of about 0.044 MPa may be included on the first protective layer 310, and a second sub-adhesive layer 402b having a high modulus of about 1000 MPa is included on the first sub-adhesive layer 402a.

A thickness of the adhesive layers ALa, ALb, and ALc of Comparative Example 1 to Comparative Example 3 may be about 75 μm. The first sub-adhesive layer (ALd) 402a of Comparative Examples 4 and 6 may have a thickness of about 25 μm, and the second sub-adhesive layer (ALe) 402b may have a thickness of about 50 μm. The first sub-adhesive layer (ALd) 402a of Comparative Examples 4 and 6 may have a thickness of about 50 μm, and the second sub-adhesive layer (ALe) 402b may have a thickness of about 25 μm.

TABLE 1

| | | | | Comparative | |
|---|---|---|---|---|---|
| | | | | Example 4 and | Comparative |
| | Comparative | Comparative | Comparative | Comparative | Example 6 and |
| | Example 1 | Example 2 | Example 3 | Example 5 | Example 1 |
| Modulus of | 0.071 | 0.044 | 1000 | 0.044 | 1000 |
| adhesive layer | | | | 1000 | 0.044 |
| G′ (Mpa) | | | | | |

Referring to Table 2 below, it may be seen that in case that a sub-adhesive layer with a low modulus, as in Comparative Example 4 and Comparative Example 5 compared to Comparative Example 1, is attached to the window, impact resistance decreases and a deformation rate of the encapsulating layer is significant.

TABLE 2

| | | Compar- | Compar- | Compar- | Compar- | Compar- | Compar- | |
|---|---|---|---|---|---|---|---|---|
| | | ative | ative | ative | ative | ative | ative | |
| | | Example | Example | Example | Example | Example | Example | Example |
| | | 1 | 2 | 3 | 4 | 5 | 6 | 1 |
| Deformation | Window | 100 | 101 | 11.2 | 0.17 | 6.72 | 22.0 | 38.6 |
| rate | Encapsulation | 100 | 97.4 | 88.4 | 350 | 67.2 | 69.4 | 70.3 |
| (%) | layer | | | | | | | |

Referring to Table 3 below, based on Comparative Example 1, it can be confirmed that Comparative Examples 3, 5, and 6 are not suitable for use in a foldable display device because torque required to fold the display device increases.

TABLE 3

| | Compar- | Compar- | Compar- | Compar- | Compar- | Compar- | |
|---|---|---|---|---|---|---|---|
| | ative | ative | ative | ative | ative | ative | |
| | Example | Example | Example | Example | Example | Example | Example |
| | 1 | 2 | 3 | 4 | 5 | 6 | 1 |
| Torque (nm) | 5300 | 5270 | 5448 | 5293 | 5332 | 5334 | 5292 |

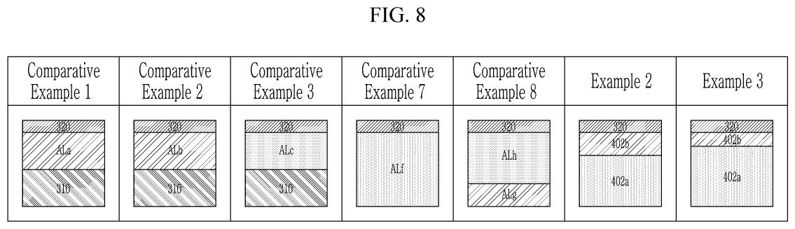

In case that FIG. 7 and Tables 1 to 3 are comprehensively considered, it may be seen that in the case of Example 1, deformation of the window and the encapsulation layer occurs in a significantly smaller amount compared to Comparative Example 1 even in case that an impact is applied from the outside. In Example 1, it can be confirmed that even in case that used in a foldable display device, the device can be folded with appropriate force. For FIG. 8 and Table 4, in Comparative Example 1, a single adhesive layer ALa having a modulus of about 0.071 MPa may be disposed between the first protective layer 310 and the window 320, in Comparative Example 2, a single adhesive layer ALb with a modulus of about 0.044 MPa may be disposed between the first protective layer 310 and the window 320, and in Comparative Example 3, a single adhesive layer ALc having a modulus of about 1000 MPa is disposed between the first protective layer 310 and the window 320. In Comparative Example 7, an adhesive layer ALf with a high modulus of about 1000 MPa may be disposed at a lower portion of the window 320 without a separate protective layer, and in Comparative Example 8, and Example 2 and Example 3, a structure may be included in which a second sub-adhesive layer (ALh) 402b with a high modulus of about 1000 MPa is disposed on a first sub-adhesive layer (ALg) 402a with a low modulus of about 0.044 MPa without a separate protective layer.

The thickness of the adhesive layers ALa, ALb, and ALc of Comparative Example 1 to Comparative Example 3 is about 75 μm. The thickness of the adhesive layer ALf in Comparative Example 7 may be about 148 μm. The first sub-adhesive layer ALg of Comparative Example 8 has a thickness of about 98 μm, and the second sub-adhesive layer ALh may have a thickness of about 50 μm. The first sub-adhesive layer 402a of Example 2 may have a thickness of about 98 μm, and the second sub-adhesive layer 402b may have a thickness of about 50 μm. The first sub-adhesive layer 402a of Example 3 may have a thickness of about 123 μm, and the second sub-adhesive layer 402b may have a thickness of about 25 μm.

TABLE 4

| | | | | | Comparative |
|---|---|---|---|---|---|
| | | | | | Example 8 |
| | Comparative | Comparative | Comparative | Comparative | and Examples |
| | Example 1 | Example 2 | Example 3 | Example 7 | 2 and 3 |
| Modulus of | 0.071 | 0.044 | 1000 | 1000 | 1000 |
| adhesive layer | | | | | 0.044 |
| G′ (Mpa) | | | | | |

Referring to Table 5 below, it may be seen that in case that an adhesive layer with a high modulus, as in Comparative Example 7 compared to Comparative Example 1, is attached to the window, impact resistance decreases and a strain rate of the encapsulating layer is significant.

TABLE 5

| | | Compar- | Compar- | Compar- | Compar- | Compar- | | |
|---|---|---|---|---|---|---|---|---|
| | | ative | ative | ative | ative | ative | | |
| | | Example | Example | Example | Example | Example | Example | Example |
| | | 1 | 2 | 3 | 7 | 8 | 2 | 3 |
| Deformation | Window | 100 | 101 | 11.2 | 0.17 | 6.72 | 22.0 | 38.6 |
| rate | Encapsulation | 100 | 97.4 | 88.4 | 350 | 67.2 | 69.4 | 70.3 |
| (%) | layer | | | | | | | |

Additionally, referring to Table 6 below, based on Comparative Example 1, it can be confirmed that Comparative Examples 3, 7, and 8 are not suitable for use in a foldable display device because torque required to fold the display device increases.

TABLE 6

| | Compar- | Compar- | Compar- | Compar- | Compar- | | |
|---|---|---|---|---|---|---|---|
| | ative | ative | ative | ative | ative | | |
| | Example | Example | Example | Example | Example | Example | Example |
| | 1 | 2 | 3 | 7 | 8 | 2 | 3 |
| Torque (nm) | 5300 | 5270 | 5448 | 6987 | 5376 | 5276 | 5255 |

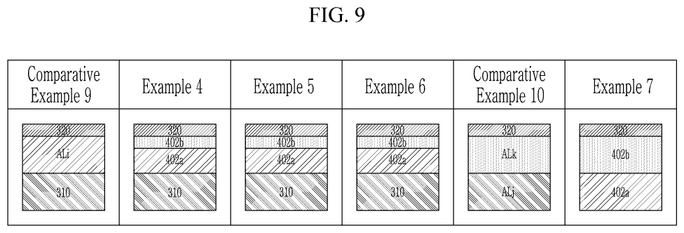

In case that Table 8 and Tables 4 to 6 are comprehensively considered, it may be seen that in the case of Example 2 and 3, deformation of the window and the encapsulation layer occurs in a significantly smaller amount compared to Comparative Example 1 even in case that subjected to an external impact. In Examples 2 and 3, it can be confirmed that even in case that used in a foldable display device, the device can be folded with appropriate force. Referring to FIG. 9 and Table 7, in Comparative Example 9, an adhesive layer ALi having a refractive index of about 1.48 and a thickness of about 75 μm may be included between the first protective layer 310 and the window 320. In Example 4, a first sub-adhesive layer 402a having a refractive index of about 1.51 and a thickness of 50 μm and a second sub-adhesive layer 402b having a refractive index of about 1.51 and a thickness of about 25 μm may be included between the first protective layer 310 and the window 320. In Example 5, a first sub-adhesive layer 402a having a refractive index of about 1.65 and a thickness of about 50 μm and a second sub-adhesive layer 402b having a refractive index of about 1.65 and a thickness of about 25 μm may be included between the protective layer 310 and the window 320. In Example 6, a first sub-adhesive layer 402a having a refractive index of about 1.65 and a thickness of about 50 μm and a second sub-adhesive layer 402b having a refractive index of about 1.51 and a thickness of about 25 μm may be included between the first protective layer 310 and the window 320. In Comparative Example 10, a first sub-adhesive layer ALj having a refractive index of about 1.65 and a thickness of about 98 μm and a second sub-adhesive layer ALk having a refractive index of about 1.51 and a thickness of about 50 μm may be included without a protective layer. In Example 7, a first sub-adhesive layer 402a having a refractive index of about 1.65 and a thickness of about 98 μm and a second sub-adhesive layer 402b having a refractive index of about 1.65 and a thickness of about 50 μm may be included without a protective layer.

It can be confirmed that relative reflectance of Example 4, where refractive indices of the first sub-adhesive layer and the second sub-adhesive layer are both about 1.51, Example 5, where refractive indices of the first sub-adhesive layer and the second sub-adhesive layer are both about 1.65, Example 6, where a refractive index of the first sub-adhesive layer is about 1.65 and a refractive index of the second sub-adhesive layer is about 1.51, and Example 7 where a refractive index of both the first sub-adhesive layer and a second sub-adhesive layer are about 1.61 without a protective layer was about 95.1%, which was lower than that of the comparative examples.

TABLE 7

| | | Compar- | | | | Compar- | |
|---|---|---|---|---|---|---|---|
| | | ative | | | | ative | |
| | | Example | Example | Example | Example | Example | Example |
| | | 9 | 4 | 5 | 6 | 10 | 7 |
| Refractive | Second | 1.48 | 1.51 | 1.65 | 1.51 | 1.51 | 1.65 |
| index | sub- | | | | | | |
| | adhesive | | | | | | |
| | layer | | | | | | |
| | First | | | | 1.65 | 1.65 | |
| | sub- | | | | | | |
| | adhesive | | | | | | |
| | layer | | | | | | |

| | | | | | | |
|---|---|---|---|---|---|---|
| Relative reflectance | 100% | 95.1% | 95.1% | 95.1% | 182% | 95.1% |

Referring to Table 8 below, a pen drop experiment was performed to confirm a degree of deformation of the window. In Comparative Example 1, an adhesive layer having a modulus of about 0.071 MPa may be included, in Example 8, an adhesive layer having a modulus of about 100 MPa may be included, in Example 9, an adhesive layer having a modulus of about 500 MPa may be included, and in Example 10, an adhesive layer having a modulus of about 1 GPa may be included. As shown in Table 8, it was confirmed that Example 8 had half deformation of Comparative Example 1, and in the case of Examples 9 and 10, it was confirmed that deformation of the window was reduced to one-tenth.

TABLE 8

| | Comparative | | | |
|---|---|---|---|---|
| | Example 1 | Example 8 | Example 9 | Example 10 |
| | (0.071 MPa) | (100 MPa) | (500 MPa) | (1 GPa) |
| Strain (%) | 100 | 46.7 | 13.2 | 11.2 |

It can be confirmed that the display device according to an embodiment may satisfy both impact resistance and folding characteristics through a first sub-adhesive layer with a relatively low modulus and a second sub-adhesive layer with a relatively high modulus. While this disclosure has been described in connection with what is presently considered to be practical embodiments, it should be understood that the disclosure is not limited to the disclosed embodiments, but, on the contrary, is intended to cover various modifications and equivalent dispositions included within the spirit and scope of the appended claims.

What is claimed is:

1. A display device comprising:
a display panel;
a protective layer disposed on the display panel;
a window disposed on the protective layer; and
an adhesive layer disposed between the window and the protective layer,
wherein the adhesive layer includes:
a first sub-adhesive layer having a first modulus; and
a second sub-adhesive layer disposed on the first sub-adhesive layer and having a second modulus, and
the second modulus of the second sub-adhesive layer is greater than the first modulus of the first sub-adhesive layer.

2. The display device of claim 1, wherein
the first modulus of the first sub-adhesive layer is about 0.1 MPa or less.

3. The display device of claim 1, wherein
the second modulus of the second sub-adhesive layer is about 100 MPa or more.

4. The display device of claim 1, wherein
a thickness of the first sub-adhesive layer is greater than a thickness of the second sub-adhesive layer in a thickness direction.

5. The display device of claim 4, wherein
the thickness of the first sub-adhesive layer is about 50 μm or more, and
the thickness of the second sub-adhesive layer is about 25 μm to about 30 μm.

6. The display device of claim 1, wherein
the protective layer has a first refractive index, and
the window has a second refractive index.

7. The display device of claim 6, wherein
the first sub-adhesive layer and the second sub-adhesive layer have the second refractive index.

8. The display device of claim 6, wherein
the first sub-adhesive layer and the second sub-adhesive layer have the first refractive index.

9. The display device of claim 6, wherein
the first sub-adhesive layer has the first refractive index, and the second sub-adhesive layer has the second refractive index.

10. The display device of claim 1, wherein
at least one of the first sub-adhesive layer or the second sub-adhesive layer includes at least one of a fluorene-based compound, a sulfone-based compound, or a TiO₂ nanocomposite.

11. A display device comprising:
a display panel;
a window disposed on the display panel; and
an adhesive layer disposed between the window and the display panel,
wherein the adhesive layer includes:
a first sub-adhesive layer having a first modulus; and
a second sub-adhesive layer disposed on the first sub-adhesive layer and having a second modulus, and
the second modulus of the second sub-adhesive layer is greater than the first modulus of the first sub-adhesive layer.

12. The display device of claim 11, wherein
the first sub-adhesive layer is in contact with the display panel.

13. The display device of claim 11, wherein
the second sub-adhesive layer is in contact with the window.

14. The display device of claim 11, wherein
the first modulus is about 0.1 MPa or less, and
the second modulus is about 100 MPa or more.

15. The display device of claim 11, wherein
a thickness of the first sub-adhesive layer is greater than a thickness of the second sub-adhesive layer in a thickness direction.

16. The display device of claim 15, wherein
the thickness of the first sub-adhesive layer is about 50 μm or more.

17. The display device of claim 16, wherein
the thickness of the second sub-adhesive layer is about 50 μm to about 60 μm.

18. The display device of claim 11, wherein
the window has a second refractive index.

19. The display device of claim 18, wherein
the first sub-adhesive layer and the second sub-adhesive layer have the second refractive index.

20. The display device of claim 11, wherein
at least one of the first sub-adhesive layer or the second sub-adhesive layer includes at least one of a fluorene-based compound, a sulfone-based compound, or a TiO₂ nanocomposite.
